(19) United States
(12) Patent Application Publication
(10) Pub. No.: US 2025/0191977 A1
(43) Pub. Date: Jun. 12, 2025

(54) METHOD OF FABRICATING ELECTRONIC CHIPS

(71) Applicant: STMicroelectronics International N.V., Geneva (CH)

(72) Inventors: Gregoire DELACOURT, TOURS (FR); Ludovic FALLOURD, Louans (FR)

(21) Appl. No.: 18/958,396

(22) Filed: Nov. 25, 2024

(30) Foreign Application Priority Data
Dec. 7, 2023 (FR) FR2313734

(51) Int. Cl. H01L 21/78; H01L 21/3105; H01L 23/31

(52) U.S. Cl. CPC H01L 21/78; H01L 21/31058; H01L 23/3185

(57) ABSTRACT

The present description relates to a method of fabricating an electronic chip with passivated flanks from a semiconductor substrate, a first face of which is covered by connection areas, and in which chips are formed, the method comprising the following steps: forming trenches or cavities between the chips; depositing an insulating material in the trenches or cavities; and separating the chips by cutting at least the insulating material.

### CROSS REFERENCE TO RELATED APPLICATION(S)

This application claims the priority benefit of French Patent Application Number 2313734, filed on Dec. 7, 2023, entitled “Procédé de fabrication de puces électroniques”, which is hereby incorporated by reference to the maximum extent allowable by law.

### TECHNICAL FIELD

The present description relates to the field of CSP (‘Chip-Scale Package’) chips. More specifically, it relates to a method for fabricating bare dice (also called “bare chips”).

### BACKGROUND

Bare chips comprise a substrate, made of semiconductor-conductor material, in which electronic circuits have been fabricated. The substrate is covered by connection areas to enable the chip to be assembled, for example, with a printed circuit board. When the chip is assembled, the connection areas are soldered or brazed to metal tracks or elements on the printed circuit board. However, during assembly, the solder may run up the flanks of the chip. Since the flanks of the chip are made of semiconductor material, this can lead to a loss of electrical performance (short-circuit, leakage current, etc.). There is therefore a need to avoid such phenomena.

Such chips are particularly interesting in many industrial fields, for example, in the automotive field.

### BRIEF SUMMARY

There is a need to improve at least some aspects of known chip fabricating methods. This is achieved by a method for fabricating an electronic chip with passivated flanks from a semiconductor substrate, a first face of which is covered by connection areas, and in which chips are formed, the method comprising the following steps:
forming trenches or cavities between the chips,
depositing an insulating material in the trenches or cavities,
separating the chips by cutting at least the insulating material.

According to an embodiment, trenches are formed, the trenches running from the first face of the substrate to a second face of the substrate.

According to an embodiment, cavities are formed by partially cutting the substrate from the first face, the depth of the cavities, preferably being between 10% and 75% of the thickness of the substrate.

According to an embodiment, the width of the trenches or cavities is between 20 and 80 μm.

According to an embodiment, prior to the step of separating the chips, the method comprises a step during which the substrate is thinned from a second face until the cavities are reached.

According to an embodiment, the insulating material comprises a polymer or a resin, preferably an epoxy or phenolic resin, and electrically insulating fillers, such as alumina or silica particles.

According to an embodiment, the insulating material is deposited by inkjet printing.

This is achieved by an electronic chip with passivated flanks comprising a semiconductor substrate having a first face covered by connection areas, a second face, and flanks, at least part of the flanks being formed by an insulating material layer extending from the first face of the substrate.

According to an embodiment, the insulating material layer extends from the first face to the second face.

According to an embodiment, a notch starting from the first face of the substrate is formed in the flanks, the notch being filled by the insulating material layer.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1A, FIG. 1B, FIG. 1C, and FIG. 1D are cross-sectional views illustrating steps in a method for fabricating a chip with passivated flanks according to a particular embodiment;

FIG. 2A, FIG. 2B, FIG. 2C, and FIG. 2D are cross-sectional views illustrating steps in a method for fabricating an electronic chip with passivated flanks according to another particular embodiment; and

FIG. 3A, FIG. 3B, FIG. 3C, FIG. 3D, and FIG. 3E are cross-sectional views illustrating steps in a method for fabricating chip with passivated flanks in another particular embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures, or to a . . . as orientated during normal use.

Unless specified otherwise, the expressions “around”, “approximately”, “substantially” and “in the order of” signify within 10%, and preferably within 5%.

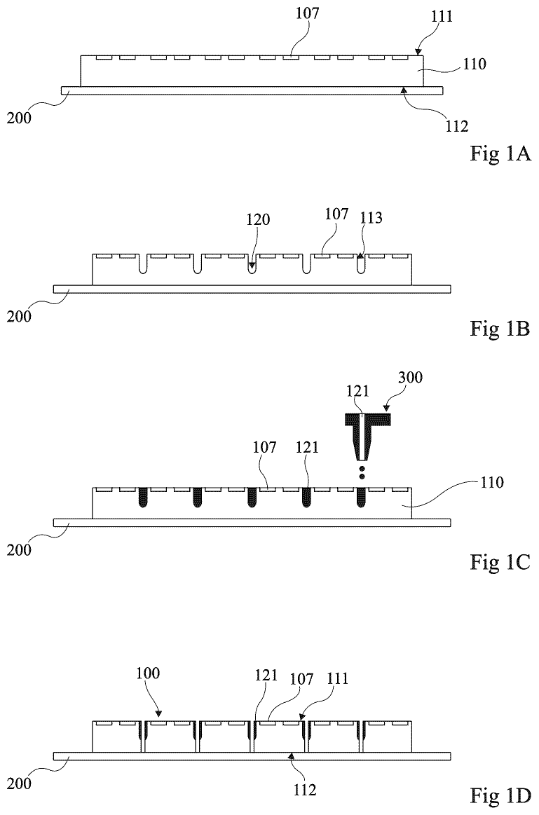

We will now describe in greater detail the fabricating method for a bare chip (also called “bare dice”) with passivated flanks, with reference to FIGS. 1A to 1D, 2A to 2D, and 3A to 3E.

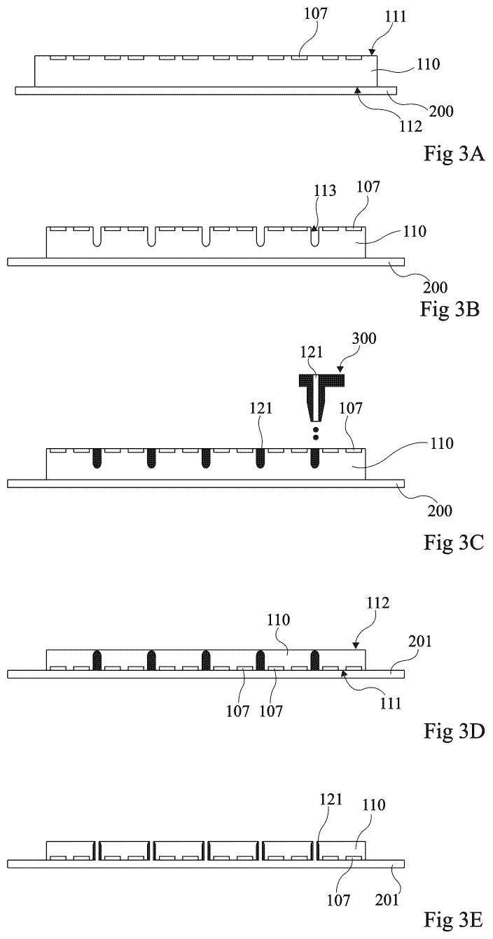

The method comprises the following steps:
a) providing a semiconductor substrate 110, a first face 111 of which is covered by connection areas 107, and in which chips 100 are formed (FIGS. 1A, 2A, 3A),
b) forming trenches or cavities 120, in the substrate 110 (wafer), between the chips 100 (FIGS. 1B, 2B, 3B),
c) depositing insulating material 121 in the trenches or cavities 120 (FIGS. 1C, 2C, 3C),
   optionally, performing a step of thinning the substrate 110 on the rear face (FIG. 3D),
d) separating the chips 100 by cutting through the insulating material layer 121 (FIGS. 1D, 2D, 3E).

With such a method, the flanks 113 of the resulting chips 100 are passivated by means of an insulating layer 121. Potential contamination (due to defective assembly with the board) is thus avoided, and there is no degradation of electrical performance.

In step a), fabricating the discrete component(s) and/or integrated circuit(s) is complete. The chips 100 are formed from a single substrate 110, and have not yet been individualized.

Substrate 110 comprises a first face 111 (top or front face) and a second face 112 (bottom or rear face or active face). The two faces 111 and 112 are parallel to each other. They are connected to each other by sidewalls.

Substrate 110 is, for example, a semiconductor substrate, such as silicon. It may also be made of SiC.

Substrate 110 has a thickness of between 100 and 900 μm, preferably between 300 and 900 μm, for example, a thickness of around 725 μm.

One or more connection areas 107 (also known as electrical contacts) are formed on the upper face 111 of the substrate 110 of the electronic chip 100, enabling it to be connected to other elements (chips or printed circuits, for example). Preferably, there are at least two connection areas.

The electrical connection areas 107 are, for example, 10 to 30 μm away from the chip sidewall. The electrical connection areas 107 can be positioned on the top surface 111 of the chip 100 or flush with the top surface 111 (i.e. flush with the top surface 111 of the chip 100).

The electrical connection areas 107 are also called “UBM” (Under Bump Metallization). Electrical connection areas 107 are made of a conductive material. Advantageously, the electrical connection areas 107 comprise at least one of the following elements: gold, titanium, nickel, copper or tungsten. Preferably, they comprise gold.

The connection pads can be formed on the connection areas 107.

The chip 100 may comprise one or more discrete components. The discrete component(s) are, for example, selected from transistors, diodes, thyristors, triacs, etc. Chip 100 may comprise one or more electronic circuits. The chip 100 can be used to implement various electronic functions.

The substrate supplied in step a) is positioned on a support 200. Support 200 is adhesive.

In step b), the substrate 110 is cut at least partially between the chips 100 to form either cavities or trenches. The cavities or trenches 120 define the lateral contours of the chips 100. More particularly, the cavities or trenches 120 extend from the top face 111 of the substrate 110.

According to a first alternative embodiment, for example shown in FIGS. 1B and 3B, cavities 120 are formed. Their depth is less than the thickness of substrate 110.

The depth of cavities 120 is, for example, between 10 and 300 μm, preferably between 20 and 250 μm.

The depth of the cavities 120 is preferably between 10 and 75% of the thickness of the substrate 110. Trench depth can be adjusted to suit the application.

The width of cavities 120 is, for example, between 20 and 80 μm.

Cavity bottoms can be flat or concave.

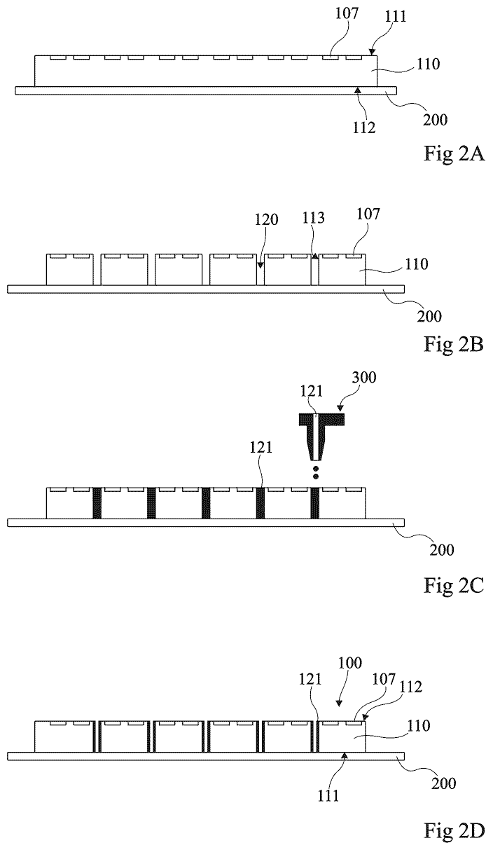

According to a second alternative embodiment, for example shown in FIG. 2B, the trenches run right through the substrate 110, i.e. the substrate 110 is cut from the first face 111 to the second face 112.

The width of the trenches 120 is, for example, between 20 and 80 μm.

This step b) is performed using a cutting device. The cutting device is, for example, a mechanical cutting/engraving tool such as a saw, or a laser engraving tool. According to a preferred embodiment, the cutting/engraving device is a laser.

To form trenches that cut right through the 110 substrate, a stealth dicing step can be performed first, followed by an expansion step. In the stealth dicing step, a special laser is used to generate dislocations within the silicon substrate, in the cutting paths. These dislocations are defects in the thickness of the substrate which, under the effect of mechanical stress, will enable the chips to be separated. Simply stretch the adhesive backing 200 to pull the chips apart and deposit the insulating material.

In step c), the trenches or cavities 120 are filled with insulating material 121 from the front face 111.

Preferably, material 121 is deposited by inkjet printing using a nozzle 300. Several passes of the nozzle may be required to fill the trenches or cavities 120.

In various embodiments, the insulating material 121 is deposited only in the cavities 120 or trenches. The front face 111 is not covered by the insulating material 121.

The material is an electrically insulating material. More particularly, material 121 comprises a base material (polymer or resin) and, preferably, electrically insulating particles. The resin is selected from the group comprising: epoxy-type resins, phenolic-type resins, acrylic-type resins. The base material can be polyvinylpyrrolidone (PVP), silicone (also known as polysiloxane), polyamic acid, tripropylene glycol diacrylate (TPGDA). The particles are, for example, oxide particles, in particular alumina or silica particles.

Preferably, the resin is a thermosetting resin or a photosensitive resin (UV). Such resins are highly stable and resistant to many chemicals.

Resin polymerization is, for example, a UV polymerization step. It can also be performed by heating or any other polymerization process chosen according to the nature of the material used.

An annealing step can be performed after step c).

The method can also include a step of thinning from the rear face (FIG. 3D). This step is preferably performed after step c). To do this, the structure is turned over and attached by its front face 111 to a support 201. Support 201 is, for example, a strip of adhesive tape. The structure is then thinned from the rear face 112 so as to give the 110 substrate its final thickness. When cavities have been formed in step b), the thinning step is preferably performed so as to thin the substrate 110 down to the cavities 120.

In step d), the chips 100 are singularised. This singularisation step can be performed by cutting through the insulating material 121 (FIG. 3E) and, if required, also by cutting through the substrate 110 (FIGS. 1D, 2D). The cutting line is centered in relation to the cavities/trenches.

The cutting device is, for example, a mechanical engraving tool such as a saw, or a laser engraving tool. According to a preferred embodiment, the cutting device is a laser.

The trench created in step d) is narrower than the trench or cavity created in step b). The trench is centered on the cavity created in step b).

At the end of the method, the resulting chips 100 comprise passivated flanks 113. Passivation is due to the presence of insulating material 121. The soldering materials do not wet the insulating material 121.

According to a first variant, only part of flank 113 is passivated (FIG. 1D). The flanks comprise a first part formed in the substrate 110, made of semiconductor material, and a second part made of insulating material 121. The insulating material 121 is housed in a notch formed in the substrate 110. The notch is a corner notch, positioned at the intersection of the first face 111 and the flank 113. The notch starts from the first face 111 and extends towards the second face 112 in a plane perpendicular to the first face 111 and the second face 112. Part of flank 113 is formed from insulating material 121, and part of first face 111 is formed from insulating material 121.

According to a second variant, the entire flank 113 is passivated (FIGS. 2D, 3E).

With such a method, the height of the flanks 113 covered by the insulating material 121 can be easily adjusted.

The chips 100 can then be attached to an external device, such as a printed circuit board or other component, by their top face 111.

To this end, a brazing material is positioned between the chip 100 and the external device. During soldering, even if the solder material runs up the wettable flanks 113 of the chips 100, they will still function correctly.

Such CSP-type electronic chips have applications in a wide range of industrial fields, and in particular in the telephony, automotive, and medical fields.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A method for fabricating an electronic chip with passivated flanks from a semiconductor substrate, a first face of which is covered by connection areas, and in which chips are formed, the method comprising:
forming trenches or cavities between the chips;
depositing an insulating material in the trenches or cavities; and
separating the chips by cutting at least the insulating material.

2. The method of claim 1, wherein trenches are formed, the trenches running from the first face of the substrate to a second face of the substrate.

3. The method of claim 1, wherein cavities are formed by partially cutting the substrate from the first face, a depth of the cavities preferably being between 10% and 75% of a thickness of the substrate.

4. The method of claim 1, wherein a width of the trenches or cavities is between 20 and 80 μm.

5. The method of claim 1, wherein the cavities are formed, the method further comprising:
thinning, prior to separating the chips, the substrate from a second face until the cavities are reached.

6. The method of claim 1, wherein the insulating material comprises a polymer or a resin, preferably an epoxy or phenolic resin, and electrically insulating fillers, such as alumina or silica particles.

7. The method of claim 1, wherein the insulating material is deposited by inkjet printing.

8. The method of claim 1, wherein the insulating material is deposited only in the cavities or the trenches and the first face is not covered by the insulating material.

9. The method of claim 1, wherein the trenches or cavities are formed between the chips;
wherein separating the chips by cutting at least the insulating material comprises cutting through the insulating material and through the substrate so that after separating the chips only part of the flanks of the chips are passivated; and
wherein the flanks comprise a first part formed in the substrate and a second part comprising the insulating material starting from the first face of the substrate.

10. An electronic chip with passivated flanks comprising a semiconductor substrate having a first face covered by connection areas, a second face, and flanks, at least part of the flanks being formed by an insulating material layer extending from the first face of the substrate.

11. The electronic chip of claim 10, wherein the insulating material layer extends from the first face to the second face.

12. The electronic chip of claim 10, wherein a notch starting from the first face of the substrate is formed in the flanks, the notch being filled by the insulating material layer.

13. The electronic chip of claim 10, wherein the first face is not covered by the insulating material.

14. The electronic chip of claim 1, wherein the flanks comprise a first part formed in the substrate and a second part comprising the insulating material starting from the first face of the substrate.
